(19) United States
(12) Patent Application Publication
(10) Pub. No.: US 2025/0231035 A1
(43) Pub. Date: Jul. 17, 2025

(54) VEHICLE NAVIGATION APPARATUS

(71) Applicant: SUBARU CORPORATION, Tokyo (JP)

(72) Inventor: Naoya OSHIMA, Tokyo (JP)

(21) Appl. No.: 18/974,926

(22) Filed: Dec. 10, 2024

(30) Foreign Application Priority Data
Jan. 11, 2024 (JP) 2024-002895

(51) Int. Cl. G01C 21/34; B60L 58/12; G07C 5/10

(52) U.S. Cl. CPC G01C 21/3469; G01C 21/3461; B60L 58/12; G07C 5/10

(57) ABSTRACT

A vehicle navigation apparatus includes a vehicle position data acquirer, a traveling candidate route searcher, an external data acquirer, and a battery remaining capacity calculator. The battery remaining capacity calculator calculates, for searched traveling candidate routes, a battery remaining capacity being upon arrival of the vehicle at a destination of corresponding one of the searched traveling candidate routes, based on a traveling condition and acquired external data. The external data acquirer acquires temperature data as the external data that is upon passing through corresponding one of the searched traveling candidate routes. The battery remaining capacity calculator calculates the battery remaining capacity being upon the arrival at the destination for each searched traveling candidate route based on the temperature data. The traveling candidate route searcher searches for one or more of the traveling candidate routes in which the battery remaining capacity is equal to or more than a predetermined amount.

### CROSS-REFERENCE TO RELATED APPLICATIONS

The present application claims priority from Japanese Patent Application No. 2024-002895 filed on Jan. 11, 2024, the entire contents of which are hereby incorporated by reference.

### BACKGROUND

The disclosure relates to a vehicle navigation apparatus.

Currently, a vehicle navigation apparatus that utilizes both map data and data on a current position of an own vehicle obtained from a satellite navigation system has been widely used. The vehicle navigation apparatus displays the current position of the own vehicle, and guides a path from the current position to a destination.

In recent years, such a vehicle navigation apparatus has undergone progress as an apparatus that has convenience of presentation of multiple optimum paths and multiple candidate paths based on required time from a current position to a destination also based on traffic data, for example.

Meanwhile, in recent years, an electric vehicle having characteristics such as an environmental consideration and silencing of traveling noise has become popular in an accelerated manner, with a momentum exceeding an existing vehicle driven by an internal combustion engine.

The electric vehicle initially has had an issue of a cruising distance, which however has been gradually improved by enhanced battery performance and facilitated preparation of charging infrastructures. The electric vehicle is also highly compatible with automated driving based on a navigation system.

Nevertheless, the greatest concern that still remains in navigating the electric vehicle is a distance to empty. A battery remaining amount, i.e., a charging rate and an electricity cost, i.e., a power consumption rate that determine the distance to empty remain important information, without any change.

In view of the above-described issues, for example, Japanese Unexamined Patent Application Publication (JP-A) No. 2019-168326 discloses a navigation apparatus for an electric vehicle that includes a traveling motor, a battery, an in-vehicle auxiliary device, and a battery management device. The battery exchanges electric power with the traveling motor. The in-vehicle auxiliary device includes an in-vehicle air conditioner operable by electric power of the battery. The battery management device includes a remaining amount estimation unit that estimates a remaining amount of the battery. The navigation apparatus includes a vehicle position detection unit, a path setting unit, a unit that estimates an electricity cost of the auxiliary device, and a unit that calculates required electric power and required time for traveling a path. The vehicle position detection unit utilizes a satellite navigation system. The path setting unit sets a path to a destination with reference to map data. The unit that estimates the electricity cost of the auxiliary device refers to weather information on a region of the path. The unit that calculates the required electric power and the required time for traveling the path considers the electricity cost of the auxiliary device and an electricity cost of traveling. The navigation apparatus notifies the battery remaining amount upon arrival at the destination and time of arrival at the destination based on the units of the navigation apparatus to thereby reflect the electricity cost of the traveling and the electricity cost of the auxiliary device on the path guiding and to expand a range of path selection to be performed by a user.

### SUMMARY

An aspect of the disclosure provides a vehicle navigation apparatus to be applied to a vehicle. The vehicle navigation apparatus includes a vehicle position data acquirer, a traveling candidate route searcher, an external data acquirer, and a battery remaining capacity calculator. The vehicle position data acquirer is configured to acquire data on a position of the vehicle. The traveling candidate route searcher is configured to search for traveling candidate routes from a current position of the vehicle to a destination of the vehicle based on the data on the position of the vehicle. The external data acquirer is configured to acquire external data. The battery remaining capacity calculator is configured to calculate, for each of the searched traveling candidate routes, a remaining capacity of a battery that is upon arrival of the vehicle at the destination of corresponding one of the searched traveling candidate routes, based on a traveling condition and the acquired external data. The external data acquirer is configured to acquire temperature data as the external data that is upon passing of the vehicle through corresponding one of the searched traveling candidate routes. The battery remaining capacity calculator is configured to calculate the remaining capacity of the battery that is upon the arrival of the vehicle at the destination for each of the searched traveling candidate routes based on the temperature data. The traveling candidate route searcher is configured to search for one or more of the traveling candidate routes in which the remaining capacity of the battery is equal to or more than a predetermined amount.

An aspect of the disclosure provides a vehicle navigation apparatus to be applied to a vehicle. The vehicle navigation apparatus includes a vehicle position data acquirer, a traveling candidate route searcher, an external data acquirer, and a battery remaining capacity calculator. The vehicle position data acquirer is configured to acquire data on a position of the vehicle. The traveling candidate route searcher is configured to search for traveling candidate routes from a current position of the vehicle to a destination of the vehicle based on the data on the position of the vehicle. The external data acquirer is configured to acquire external data. The battery remaining capacity calculator is configured to calculate, for each of the searched traveling candidate routes, a remaining capacity of a battery that is upon arrival of the vehicle at the destination of corresponding one of the searched traveling candidate routes based on a traveling condition. The traveling candidate route searcher is configured, when there is a section where a temperature upon passing of the vehicle is equal to or lower than a predetermined temperature, to search for one or more of the traveling candidate routes in which the remaining capacity of the battery is equal to or more than a predetermined amount, based on the external data, out of the traveling candidate routes that include a traveling candidate route having the section where the vehicle does not travel for predetermined time or more.

An aspect of the disclosure provides a vehicle navigation apparatus to be applied to a vehicle. The vehicle navigation apparatus includes circuitry. The circuitry is configured to: acquire data on a position of the vehicle; search for traveling candidate routes from a current position of the vehicle to a destination of the vehicle based on the data on the position of the vehicle; acquire external data; and calculate, for each of the searched traveling candidate routes, a remaining capacity of a battery that is upon arrival of the vehicle at the destination of corresponding one of the searched traveling candidate routes, based on a traveling condition and the acquired external data. The circuitry is configured to acquire temperature data as the external data that is upon passing of the vehicle through corresponding one of the searched traveling candidate routes; calculate the remaining capacity of the battery that is upon the arrival of the vehicle at the destination for each of the searched traveling candidate routes based on the temperature data; and search for one or more of the traveling candidate routes in which the remaining capacity of the battery is equal to or more than a predetermined amount.

An aspect of the disclosure provides a vehicle navigation apparatus to be applied to a vehicle. The vehicle navigation apparatus includes circuitry. The circuitry is configured to: acquire data on a position of the vehicle, search for traveling candidate routes from a current position of the vehicle to a destination of the vehicle based on the data on the position of the vehicle; acquire external data; and calculate, for each of the searched traveling candidate routes, a remaining capacity of a battery that is upon arrival of the vehicle at the destination of corresponding one of the searched traveling candidate routes based on a traveling condition. The circuitry is configured to search, when there is a section where a temperature upon passing of the vehicle is equal to or lower than a predetermined temperature, for one or more of the traveling candidate routes in which the remaining capacity of the battery is equal to or more than a predetermined amount, based on the external data, out of the traveling candidate routes that include a traveling candidate route having the section where the vehicle does not travel for predetermined time or more.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the disclosure.

FIG. 1 is a diagram illustrating a configuration of a vehicle navigation apparatus according to one example embodiment of the disclosure.

FIG. 2 is a diagram illustrating a search result of traveling candidate routes in the vehicle navigation apparatus illustrated in FIG. 1.

FIG. 3 is a diagram illustrating a display example of the traveling candidate routes presented by the vehicle navigation apparatus illustrated in FIG. 1.

FIG. 4 is a diagram illustrating processing of the vehicle navigation apparatus illustrated in FIG. 1.

FIG. 5 is a diagram illustrating a configuration of a vehicle navigation apparatus according to one example embodiment of the disclosure.

FIG. 6 is a diagram illustrating a search result of traveling candidate routes in the vehicle navigation apparatus illustrated in FIG. 5.

FIG. 7 is a diagram illustrating a display example of the traveling candidate routes presented by the vehicle navigation apparatus illustrated in FIG. 5.

FIG. 8 is a diagram illustrating processing of the vehicle navigation apparatus illustrated in FIG. 5.

FIG. 9 is a diagram illustrating a configuration of a vehicle navigation apparatus according to one example embodiment of the disclosure.

FIG. 10 is a diagram illustrating processing of the vehicle navigation apparatus illustrated in FIG. 9.

### DETAILED DESCRIPTION

In the following, some example embodiments of the disclosure are described in detail with reference to the accompanying drawings.

Note that the following description is directed to illustrative examples of the disclosure and not to be construed as limiting to the disclosure. Factors including, without limitation, numerical values, shapes, materials, components, positions of the components, and how the components are coupled to each other are illustrative only and not to be construed as limiting to the disclosure. Further, elements in the following example embodiments which are not recited in a most-generic independent claim of the disclosure are optional and may be provided on an as-needed basis. The drawings are schematic and are not intended to be drawn to scale. Throughout the present specification and the drawings, elements having substantially the same function and configuration are denoted with the same reference numerals to avoid any redundant description. In addition, elements that are not directly related to any embodiment of the disclosure are unillustrated in the drawings.

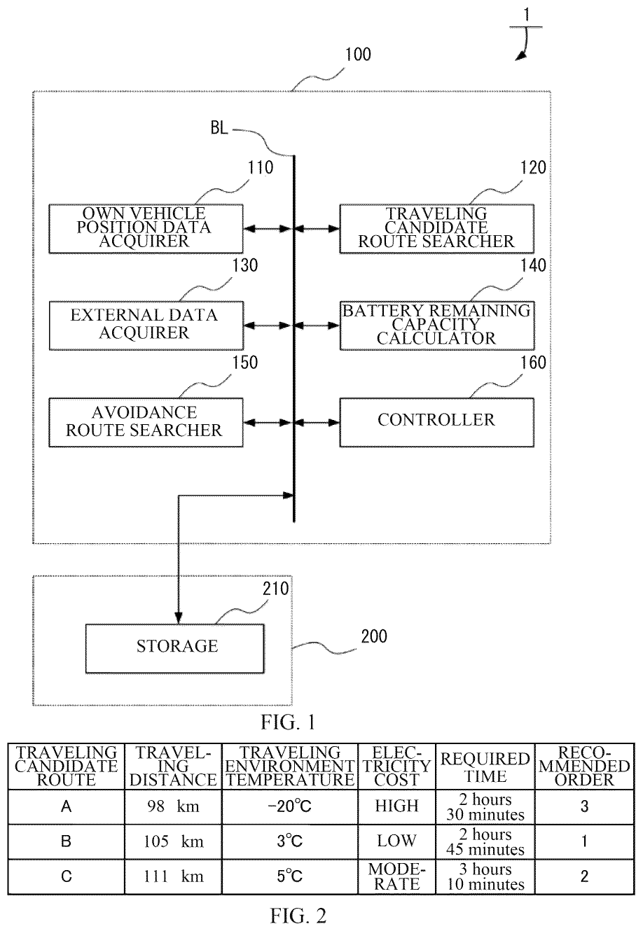

A description is given of a vehicle navigation apparatus with reference to FIGS. 1 to 10.

To address remarkable popularization of electric vehicles in the future, various in-vehicle batteries that ensure factors such as cost and safety have been currently developed, and such in-vehicle batteries have been mounted on the electric vehicles.

However, there is a possibility that some of current mainstream lithium-ion batteries mounted on electric vehicles can cause deposition of metal lithium upon charging in a low-temperature environment of 0° C. or lower, for example. It is pointed out that the deposition of metal lithium can lead to formation of a dendrite short circuit that might possibly induce ignition.

To put it conversely, the use of the lithium-ion batteries in a recommended use environment enables ensured safety as well as enjoyment of a high discharge capacity rate at low cost.

A technique described in JP-A No. 2019-168326 fails to disclose the matters as described above, while there is a disclosure of “referring to weather information on a region of a path”. However, the term “weather information on a region of a path” is merely used to estimate an operational status of an auxiliary device.

It is desirable to provide a vehicle navigation apparatus that allows for guidance of a vehicle to a destination as well as prevention of deteriorated performance of a battery.

### First Example Embodiment

A description is given of a vehicle navigation apparatus 1 according to an example embodiment with reference to FIGS. 1 to 4.

### <Vehicle Navigation Apparatus 1>

As illustrated in FIG. 1, the vehicle navigation apparatus 1 according to the example embodiment may include a processor 100 and a memory 200.

The processor 100 may execute various pieces of processing in searching for traveling candidate routes.

In the example embodiment, for example, the processor 100 may acquire temperature data as external data, may calculate a battery remaining capacity that is upon arrival at a destination and based on the temperature data, and may search for and present traveling candidate routes in which the battery remaining capacity is equal to or more than a predetermined amount.

Note that a detailed description is given later of each processing.

The memory 200 may include a read only memory (ROM) or a random access memory (RAM), for example, and may retain and store a program and various pieces of data.

The memory 200 may include a storage 210, and may retain and store, for example, a control program of the vehicle navigation apparatus 1, map data, or, for example, data on temperatures in the traveling candidate routes, as acquired external data.

### <Configuration of Processor 100>

As illustrated in FIG. 1, the processor 100 of the vehicle navigation apparatus 1 according to the example embodiment may include an own vehicle position data acquirer 110, a traveling candidate route searcher 120, an external data acquirer 130, a battery remaining capacity calculator 140, an avoidance route searcher 150, and a controller 160. In one embodiment, the own vehicle position data acquirer 110 may serve as a “vehicle position data acquirer”.

As illustrated in FIG. 1, the above-described components may be coupled to one another via a bus line BL.

The own vehicle position data acquirer 110 may acquire data on a position of an own vehicle.

In one example, the own vehicle position data acquirer 110 may measure, for example, time in which radio waves constantly emitted from multiple satellites reach a receiver mounted on the own vehicle by utilizing a global navigation satellite system (GNSS) such as a global positioning system (GPS) to acquire the data on the position of the own vehicle.

The data on the position of the own vehicle acquired by the own vehicle position data acquirer 110 may be outputted to the controller 160 described later via the bus line BL.

The traveling candidate route searcher 120 may search for multiple traveling candidate routes that includes an optimum route and candidate routes from a current position to the destination based on the data on the position of the own vehicle, destination data instructed by a user, and map data stored in the storage 210.

The traveling candidate route searcher 120 may further search for traveling candidate routes in which the battery remaining capacity calculated by the battery remaining capacity calculator 140 described later is equal to or more than a predetermined amount upon the arrival at the destination, for the multiple traveling candidate routes described above, and may present the searched traveling candidate routes to the user.

As illustrated in FIG. 2, the traveling candidate route searcher 120 may classify electricity costs, of the multiple traveling candidate routes, into three stages of “low”, “mediate”, and “high”, for example, based on a result of the calculation performed by the battery remaining capacity calculator 140 described later.

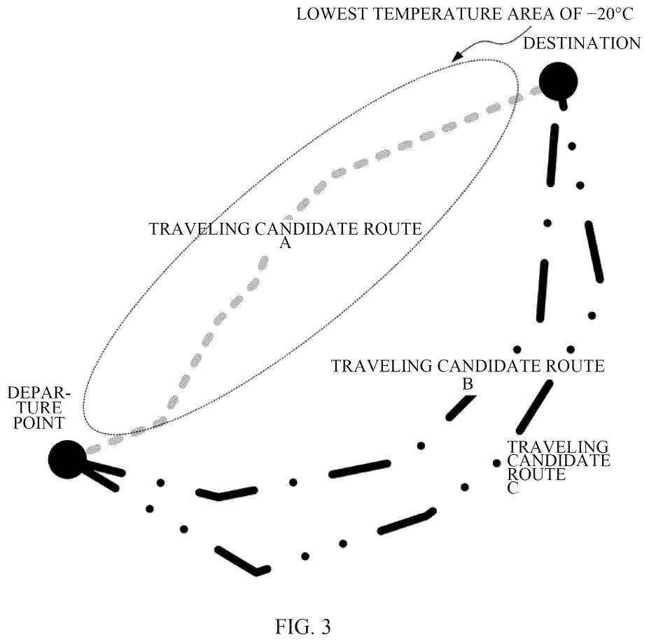

For example, a traveling candidate route A, a traveling candidate route B, and a traveling candidate route C may be calculated as traveling candidate routes. The traveling candidate route A may have a traveling distance of “98 km”, a traveling environmental temperature, i.e., a lowest traveling path temperature of “−20° C., an electricity cost of “high”, and required time of “2 hours and 30 minutes”. The traveling candidate route A is indicated, in FIG. 3, by a dotted line. The traveling candidate route B may have a traveling distance of “105 km”, a traveling environmental temperature, i.e., a lowest traveling path temperature of “+3° C.”, an electricity cost of “low”, and required time of “2 hours and 45 minutes”. The traveling candidate route B is indicated, in FIG. 3, by a one-dot chain line. The traveling candidate route C may have a traveling distance of “111 km”, a traveling environmental temperature, i.e., a lowest traveling path temperature of “+5° C.”, an electricity cost of “moderate”, and required time of “3 hours and 10 minutes”. The traveling candidate route C is indicated, in FIG. 3, by a two-dot chain line. In such a case, for example, the traveling candidate route A may be set as the third recommended order; the traveling candidate route B may be set as the first recommended order, i.e., an optimum route; and the traveling candidate route C may be set as the second recommended order, based on the electricity cost and the required time. As illustrated in FIG. 3, the traveling candidate routes B and C may be presented to the user, excluding the traveling candidate route A which fails to satisfy a condition in terms of the electricity cost.

A result of the searching for the traveling routes performed by the traveling candidate route searcher 120 may be outputted to the controller 160 described later via the bus line BL.

The external data acquirer 130 may acquire external data.

In the example embodiment, non-limiting examples of the external data may include data on temperatures that are upon traveling of the own vehicle in the traveling candidate routes searched by the traveling candidate route searcher 120.

The external data acquirer 130 may acquire, as the external data, the data on temperatures that are upon traveling of the own vehicle in the candidate routes searched by the traveling candidate route searcher 120, for example, from a user terminal to which an application program related to weather data is downloaded.

The external data acquired by the external data acquirer 130 may be outputted to the controller 160 described later via the bus line BL.

The battery remaining capacity calculator 140 may calculate, based on a traveling condition and the external data acquired by the external data acquirer 130, a battery remaining capacity that is upon arrival of the own vehicle at the destination of corresponding one of the candidate routes searched by the traveling candidate route searcher 120.

As used herein, the term “traveling condition” may include data on a traveling path, e.g., factors such as a road shape, a gradient, and a traveling distance.

The battery remaining capacity calculator 140 may combine the battery remaining capacity that is upon the arrival of the own vehicle at the destination of corresponding one of the candidate routes based on the traveling condition with a battery remaining capacity as a result of deteriorated performance of the battery based on external data, to calculate the battery remaining capacity that is upon the arrival of the own vehicle at the destination. The candidate routes may be searched by the traveling candidate route searcher 120. The external data may be, for example, the data on temperatures that are upon traveling of the own vehicle in the candidate routes searched by the traveling candidate route searcher 120.

In the example embodiment, the own vehicle may be mounted with a battery including, for example, an iron phosphate-based lithium-ion battery of which the performance can possibly be deteriorated in a low-temperature environment of 0° C. or lower.

From those described above, the calculation of the battery remaining capacity as a result of the deteriorated performance of the battery performed by the battery remaining capacity calculator 140 may be directed to, for example, a section where a temperature upon the traveling of the own vehicle in the traveling candidate route is 0° C. or lower.

The data on the battery remaining capacity calculated by the battery remaining capacity calculator 140 may be outputted to the controller 160 described later via the bus line BL.

The avoidance route searcher 150 may search for an optimum avoidance route based on, for example, the result of the searching for the traveling routes performed by the traveling candidate route searcher 120 and the external data acquired by the external data acquirer 130.

Data on the avoidance route searched by the avoidance route searcher 150 may be outputted to the controller 160 described later via the bus line BL.

The controller 160 may execute processing of the entirety of the vehicle navigation apparatus 1 based on a control program stored, for example, in the read only memory (ROM) inside the storage 210.

The controller 160 may cause, for example: the own vehicle position data acquirer 110 to execute processing of own vehicle position data acquisition; the traveling candidate route searcher 120 to execute processing of traveling candidate route searching; the external data acquirer 130 to execute processing of external data acquisition; the battery remaining capacity calculator 140 to execute processing of battery remaining capacity calculation; and the avoidance route searcher 150 to execute processing of avoidance route searching.

In one example, the controller 160 may cause the external data acquirer 130 to acquire temperature data as the external data that is upon passing through the multiple traveling candidate routes searched by the traveling candidate route searcher 120.

The controller 160 may cause the battery remaining capacity calculator 140 to calculate, based on the temperature data, the battery remaining capacity that is upon the arrival of the own vehicle at the destination for each of the multiple traveling candidate routes searched by the traveling candidate route searcher 120.

The controller 160 may then cause the avoidance route searcher 150 to search for the avoidance route based on the multiple traveling candidate routes searched by the traveling candidate route searcher 120.

### <Processing of Vehicle Navigation Apparatus 1>

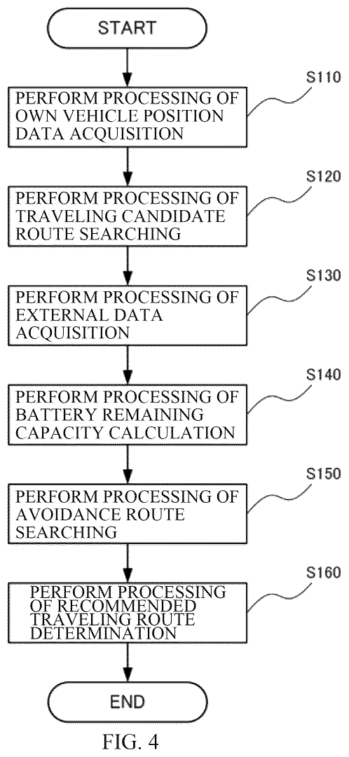

A description is given, with reference to FIG. 4, of processing of the vehicle navigation apparatus 1 according to the example embodiment.

The own vehicle position data acquirer 110 may measure, for example, time in which radio waves constantly emitted from multiple satellites reach a receiver mounted on the own vehicle by utilizing the global navigation satellite system (GNSS) to acquire the data on the position of the own vehicle (step S110).

The data on the position of the own vehicle acquired by the own vehicle position data acquirer 110 may be outputted to the controller 160 described later via the bus line BL.

The traveling candidate route searcher 120 may search for multiple traveling candidate routes from a current position to a destination based on the data on the position of the own vehicle, destination data instructed by the user, and map data stored in the storage 210 (step S120).

Data on the multiple traveling candidate routes from the current position to the destination searched by the traveling candidate route searcher 120 may be outputted to the controller 160 via the bus line BL, and the controller 160 may cause the storage 210 to temporarily retain the data on the multiple traveling candidate routes.

The external data acquirer 130 may acquire, as the external data, the data on temperatures that are upon traveling of the own vehicle in the traveling candidate routes searched by the traveling candidate route searcher 120, for example, from the user terminal to which an application program related to weather data is downloaded (step S130).

The data on temperatures that are upon traveling of the own vehicle in the traveling candidate routes acquired by the external data acquirer 130 may be outputted to the controller 160 via the bus line BL, and the controller 160 may cause the storage 210 to temporarily retain the data on the temperatures that are upon traveling of the own vehicle in the traveling candidate routes.

The battery remaining capacity calculator 140 may calculate, based on the traveling condition and the external data acquired by the external data acquirer 130, the battery remaining capacity that is upon the arrival of the own vehicle at the destination of corresponding one of the candidate routes searched by the traveling candidate route searcher 120 (step S140).

Data on the battery remaining capacity calculated by the battery remaining capacity calculator 140 may be outputted to the controller 160 via the bus line BL, and the controller 160 may cause the storage 210 to temporarily retain the data on the battery remaining capacity.

Based on the search result of the multiple traveling routes searched by the traveling candidate route searcher 120 in step S120 and the external data acquired by the external data acquirer 130 in step S130, for example, the avoidance route searcher 150 may search for an optimum avoidance route (step S150).

The traveling candidate route searcher 120 may search, with respect to the avoidance route searched by the avoidance route searcher 150, traveling candidate routes again in which the battery remaining capacity calculated by the battery remaining capacity calculator 140 in step S140 is equal to or more than a predetermined amount upon the arrival at the destination. The traveling candidate route searcher 120 may then determine a recommended traveling route, and may present the determined recommended traveling route to the user to finish the processing (step S160).

### Workings and Example Effects

As described above, the vehicle navigation apparatus 1 according to the example embodiment may include the own vehicle position data acquirer 110, the traveling candidate route searcher 120, the external data acquirer 130, and the battery remaining capacity calculator 140. The own vehicle position data acquirer 110 may acquire the data on the position of the own vehicle. The traveling candidate route searcher 120 may search for one or more of the traveling candidate routes from the current position to the destination based on the data on the position of the own vehicle.

The external data acquirer 130 may acquire the external data. The battery remaining capacity calculator 140 may calculate, for each of the searched multiple traveling candidate routes, the battery remaining capacity that is upon the arrival of the own vehicle at the destination of corresponding one of the searched traveling candidate routes, based on the traveling condition and the acquired external data. The external data acquirer 130 may acquire, as the external data, the temperature data that is upon passing through the searched multiple traveling candidate routes. The battery remaining capacity calculator 140 may calculate the battery remaining capacity that is upon the arrival at the destination for each of the searched multiple traveling candidate routes based on the temperature data. The traveling candidate route searcher 120 may search for one or more of the traveling candidate routes in which the battery remaining capacity is equal to or more than a predetermined amount.

For example, the external data acquirer 130 may acquire the temperature data as the external data that is upon passing through the searched multiple traveling candidate routes; the battery remaining capacity calculator 140 may calculate the battery remaining capacity that is upon the arrival at the destination for each of the searched multiple traveling candidate routes based on the temperature data; and the traveling candidate route searcher 120 may search for one or more of the traveling candidate routes in which the battery remaining capacity is equal to or more than a predetermined amount.

The battery remaining capacity calculator 140 may calculate the battery remaining capacity that is upon the arrival at the destination based on, in addition to the traveling condition, the temperature data as the external data that is upon passing through the searched multiple traveling candidate routes. One reason for this is that there is a possibility that the vehicle may be mounted with a battery of which the performance can possibly be deteriorated at a low temperature, e.g., at 0° C. or lower.

Accordingly, the traveling candidate route searcher 120 may search for one or more of the traveling candidate routes in which the battery remaining capacity that is upon the arrival at the destination calculated by the battery remaining capacity calculator 140 is equal to or more than a predetermined amount, and may present the searched traveling candidate routes to the user, thereby controlling a use environment of the battery even when the vehicle is mounted with the battery of which the performance can possibly be deteriorated due to the use environment. This helps to appropriately guide the vehicle to the destination and prevent deteriorated performance of the battery.

In some embodiments, the external data acquirer 130 may acquire the temperature data as the external data that is upon passing through the searched multiple traveling candidate routes based on the user terminal.

For example, the external data acquirer 130 may acquire the temperature data as the external data that is upon passing through respective points of the searched multiple traveling candidate routes based on, for example, the user terminal to which an application program related to the weather data is downloaded.

The battery remaining capacity calculator 140 may estimate vehicle traveling time in an area where the performance of the battery can possibly be deteriorated, based on the external data from the external data acquirer 130 in addition to the traveling condition, and may calculate the battery remaining capacity that is upon the arrival of the vehicle at the destination also based on an amount of decrease in the calculated battery capacity.

The traveling candidate route searcher 120 may search for one or more of the traveling candidate routes based on, as an index, a result of the calculation performed by the battery remaining capacity calculator 140, and may present the searched traveling candidate routes to the user.

The use environment of the battery may be controlled even when the vehicle is mounted with the battery of which the performance can possibly be deteriorated due to the use environment. This accordingly helps to appropriately guide the vehicle to the destination and prevent deteriorated performance of the battery.

In addition, the acquisition of the temperature data as the external data based on the user terminal helps to acquire desired information without constructing an elaborate system.

In some embodiments, the battery may include an iron phosphate-based lithium-ion battery.

There is a possibility that some of current mainstream lithium-ion batteries mounted on electric vehicles may cause deposition of metal lithium upon charging in a low-temperature environment of 0° C. or lower, for example. It is pointed out that the deposition of metal lithium may possibly lead to formation of a dendrite short circuit that induces ignition; one example thereof may be the battery including the iron phosphate-based lithium-ion battery.

Not all the vehicles are mounted with this type of battery. However, in the vehicle navigation apparatus 1 according to the example embodiment, the battery remaining capacity calculator 140 may calculate the battery remaining capacity that is upon the arrival at the destination based on a factor based on the use environment in addition to the traveling condition, and the traveling candidate route searcher 120 may search for one or more of the traveling candidate routes based on, as an index, the result of the calculation performed by battery remaining capacity calculator 140 and may present the searched traveling candidate routes to the user.

The use environment of the battery may be controlled even when the vehicle is mounted with the battery of which the performance can possibly be deteriorated due to the use environment. This accordingly helps to appropriately guide the vehicle to the destination and prevent deteriorated performance of the battery.

### Modification Example 1

In the example embodiment, the flow has been exemplified in which the series of processing are performed in the order of the processing of the traveling candidate route searching (step S120), the processing of the external data acquisition (step S130), the processing of the battery remaining capacity calculation (step S140), and the processing of the avoidance route searching (step S150). However, the series of processing may be performed in the order of the processing of the external data acquisition (step S130), the processing of the traveling candidate route searching (step S120), and the processing of the battery remaining capacity calculation (step S140).

### Second Example Embodiment

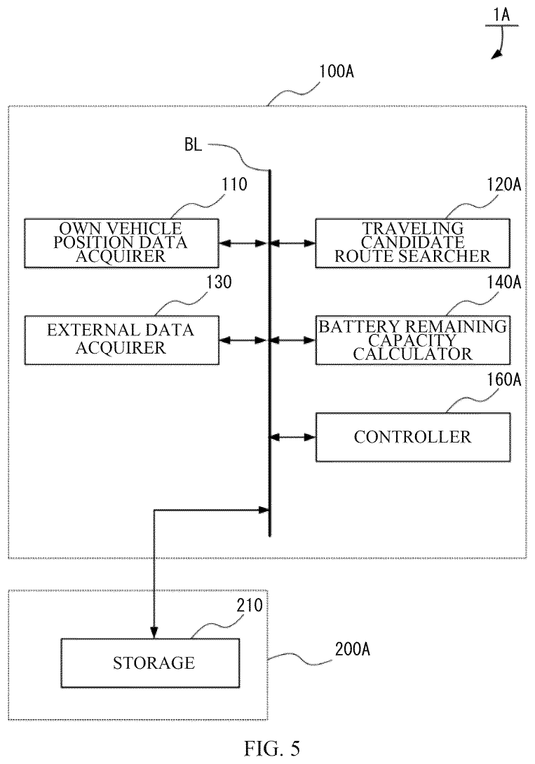

A description is given, with reference to FIGS. 5 to 8, of a vehicle navigation apparatus 1A according to the example embodiment.

In the first embodiment, the traveling candidate routes may be searched based on a current position of the own vehicle, the destination, and the map data. Thereafter, when there is a low-temperature area, for example, in some of the searched traveling candidate routes, the battery remaining capacity that is upon the arrival at the destination may be calculated based on the factor based on the use environment in addition to the traveling condition, and the traveling candidate routes in which the battery remaining capacity that is upon the arrival at the destination is equal to or more than a predetermined amount may be presented to the user.

However, in the example embodiment, even when there is a section, where a temperature upon passing of the own vehicle is equal to or lower than a predetermined temperature, on the searched traveling candidate routes, traveling candidate routes having the section where the own vehicle does not travel for predetermined time or more may also be set as searching targets. Traveling candidate routes in which the battery remaining capacity that is upon the arrival at the destination is equal to or more than a predetermined amount may be presented to the user based on the traveling condition.

### <Vehicle Navigation Apparatus 1A>

As illustrated in FIG. 5, the vehicle navigation apparatus 1A according to the example embodiment may include a processor 100A and a memory 200A.

The processor 100A may execute various pieces of processing in searching for traveling candidate routes.

In the example embodiment, even when there is a section, where the temperature upon passing of the own vehicle is equal to or lower than a predetermined temperature, on the searched traveling candidate routes, for example, the processor 100A may also set, as searching targets, traveling candidate routes having the section where the own vehicle does not travel for predetermined time or more.

Note that a detailed description is given later of each processing.

The memory 200A may include the read only memory (ROM) or the random access memory (RAM), for example, and may retain and store a program and various pieces of data.

In the example embodiment, the memory 200A may include the storage 210, and may retain and store, for example, a control program of the vehicle navigation apparatus 1, map data, or, for example, data on a section where the temperature upon the passing of the own vehicle is equal to or lower than a predetermined temperature.

### <Configuration of Processor 100A>

As illustrated in FIG. 5, the processor 100A of the vehicle navigation apparatus 1A according to the example embodiment may include the own vehicle position data acquirer 110, a traveling candidate route searcher 120A, the external data acquirer 130, a battery remaining capacity calculator 140A, and a controller 160A.

Note that components denoted by the same reference numerals as those in the first example embodiment have similar operations, and thus detailed descriptions thereof are omitted.

As illustrated in FIG. 5, the above-described components may be coupled to one another via the bus line BL.

The traveling candidate route searcher 120A may search for multiple traveling candidate routes, which includes an optimum route and candidate routes, from the current position to the destination. The searching for the multiple traveling candidate routes may be performed based on, the data on the position of the own vehicle, the destination data instructed by the user, the map data stored in the storage 210, and the data on the section where the temperature upon the passing of the own vehicle is equal to or lower than a predetermined temperature.

The traveling candidate route searcher 120A may further search for traveling candidate routes in which the battery remaining capacity calculated by the battery remaining capacity calculator 140 described later is equal to or more than a predetermined amount, for the multiple traveling candidate routes described above, and may present the searched traveling candidate routes to the user.

The traveling candidate route searcher 120A may search for multiple traveling candidate routes, which includes an optimum route and candidate routes, from the current position to the destination. The multiple traveling candidate routes may include a route having the section where the temperature upon the passing of the own vehicle is equal to or lower than a predetermined temperature and where the own vehicle does not travel for predetermined time or more.

As used herein, the term “predetermined time” refers to traveling time with verification in which no deterioration is seen in the performance of a portion of the battery, for example, even when the own vehicle travels the section where the temperature upon the passing of the own vehicle is equal to or lower than a predetermined temperature. For example, non-limiting examples thereof may include 30 minutes at a temperature of 0° C. or lower, in accordance with knowledge based on demonstration.

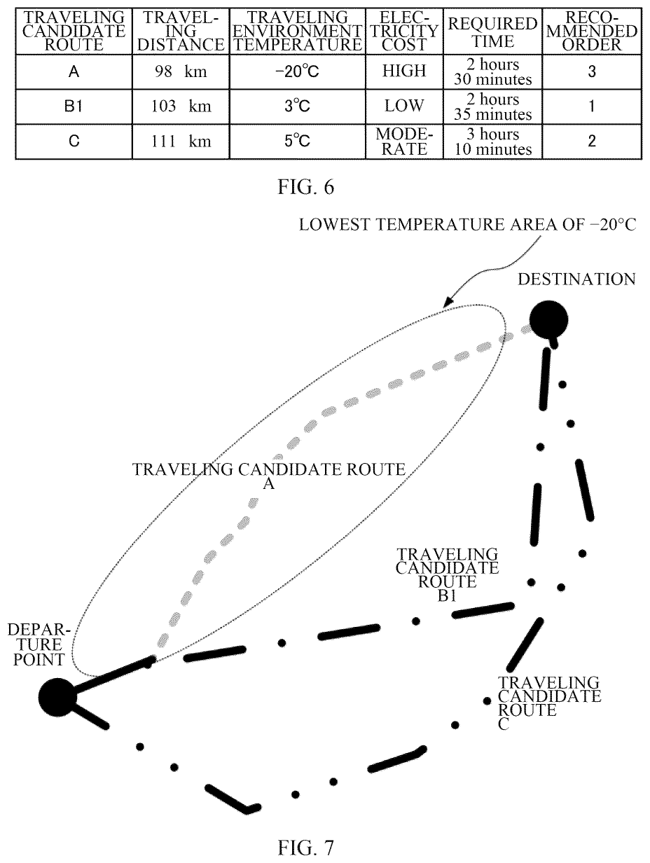

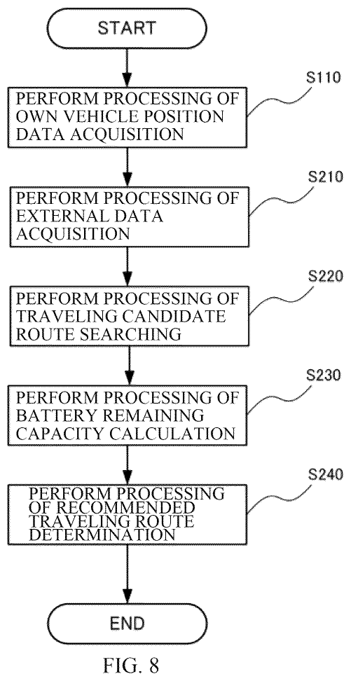

FIGS. 6 and 7 illustrate an example of traveling candidate routes searched by the traveling candidate route searcher 120A.

As illustrated in FIG. 6, the traveling candidate route searcher 120A may calculate, as the multiple traveling candidate routes, the traveling candidate route A, a traveling candidate route B1, and the traveling candidate route C, also based on the result of the calculation performed by the battery remaining capacity calculator 140A described later. The traveling candidate route A may have a traveling distance of “98 km”, a traveling environmental temperature, i.e., a lowest traveling path temperature of “−20° C., an electricity cost of “high”, and required time of “2 hours and 30 minutes”. The traveling candidate route A is indicated, in FIG. 7, by a dotted line. The traveling candidate route B1 may have a traveling distance of “103 km”, a traveling environmental temperature, i.e., a lowest traveling path temperature of “+3° C.”, an electricity cost of “low”, and required time of “2 hours and 35 minutes”. The traveling candidate route B1 is indicated, in FIG. 7, by a one-dot chain line. The traveling candidate route C may have a traveling distance of “111 km”, a traveling environmental temperature, i.e., a lowest traveling path temperature of “+5° C.”, an electricity cost of “moderate”, and required time of “3 hours and 10 minutes”. The traveling candidate route C is indicated, in FIG. 7, by a two-dot chain line. In such a case, for example, the traveling candidate route A may be set as the third recommended order; the traveling candidate route B1 may be set as the first recommended order, i.e., an optimum route; and the traveling candidate route C may be set as the second recommended order, based on the electricity cost and the required time. As illustrated in FIG. 7, the traveling candidate routes B1 and C may be presented to the user, excluding the traveling candidate route A which fails to satisfy a condition in terms of the electricity cost.

A result of searching for traveling routes performed by the traveling candidate route searcher 120A may be outputted to the controller 160A described later via the bus line BL.

The battery remaining capacity calculator 140A may calculate a battery remaining capacity that is upon arrival of the own vehicle at a destination of corresponding one of traveling candidate routes searched by the traveling candidate route searcher 120A based on the traveling condition.

As used herein, the term “traveling condition” may include data on a traveling path, e.g., factors such as a road shape, a gradient, and a traveling distance.

As described above, in a route having a section where the temperature upon passing of the own vehicle is equal to or lower than a predetermined temperature and where the own vehicle does not travel for predetermined time or more, it is verified with knowledge that no deterioration is seen in the performance of a battery of which deteriorated performance is a concern at a low-temperature state. Accordingly, the battery remaining capacity calculator 140A may calculate, based on the traveling condition, the battery remaining capacity that is upon the arrival of the own vehicle at the destination of corresponding one of the traveling candidate routes searched by the traveling candidate route searcher 120A.

In the example embodiment, the own vehicle may be mounted with a battery including, for example, an iron phosphate-based lithium-ion battery of which the performance can possibly be deteriorated at a low-temperature environment of 0° C. or lower.

The data on the battery remaining capacity calculated by the battery remaining capacity calculator 140A may be outputted to the controller 160A described later via the bus line BL.

The controller 160A may execute processing of the entirety of the vehicle navigation apparatus 1A based on a control program stored, for example, in the read only memory (ROM) inside the storage 210.

The controller 160A may cause, for example: the own vehicle position data acquirer 110 to execute the processing of the own vehicle position data acquisition; the traveling candidate route searcher 120A to execute processing of traveling candidate route searching; the external data acquirer 130 to execute the processing of the external data acquisition; and the battery remaining capacity calculator 140A to execute processing of battery remaining capacity calculation.

In one example, the controller 160A may cause the external data acquirer 130 to acquire temperature data as external data on a region from a current position to the destination.

In addition, the controller 160A may cause the battery remaining capacity calculator 140A to calculate the battery remaining capacity that is upon the arrival of the own vehicle at the destination based merely on the traveling condition, for certain traveling candidate routes. The certain traveling candidate routes may not include a section where the temperature upon the passing of the own vehicle is equal to or lower than a predetermined temperature, or may include the section where the temperature upon the passing of the own vehicle is equal to or lower than the predetermined temperature but where the own vehicle travels for predetermined time or less.

Then, the controller 160A may cause the traveling candidate route searcher 120A to search for traveling candidate routes in which the battery remaining capacity is equal to or more than a predetermined amount out of the searched multiple traveling candidate routes.

### <Processing of Vehicle Navigation Apparatus 1A>

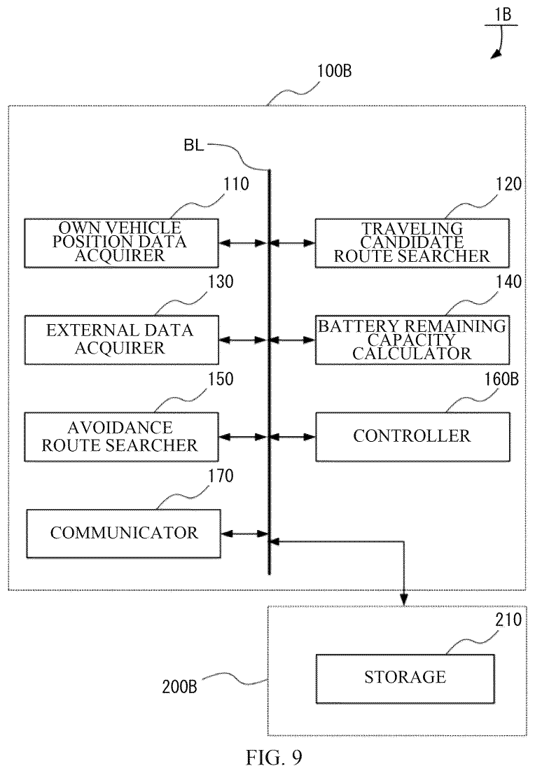

A description is given, with reference to FIG. 8, of processing of the vehicle navigation apparatus 1A according to the example embodiment.

The own vehicle position data acquirer 110 may measure, for example, time in which radio waves constantly emitted from multiple satellites reach a receiver mounted on the own vehicle by utilizing the global navigation satellite system (GNSS) to acquire the data on the position of the own vehicle (step S110).

The data on the position of the own vehicle acquired by the own vehicle position data acquirer 110 may be outputted to the controller 160A described later via the bus line BL.

The external data acquirer 130 may acquire the temperature data as the external data on the region from the current position to the destination, for example, from a user terminal to which an application program related to weather data is downloaded (step S210).

The temperature data on the region from the current position to the destination acquired by the external data acquirer 130 may be outputted to the controller 160A via the bus line BL, and the controller 160A may cause the storage 210 to temporarily retain the temperature data on the region from the current position to the destination.

The traveling candidate route searcher 120A may search for multiple traveling candidate routes including an optimum route and candidate routes from the current position to the destination, based on the data on the position of the own vehicle, destination data instructed by the user, the map data stored in the storage 210, and the data obtained by the external data acquirer 130 on the section where the temperature upon passing of the own vehicle is equal to or lower than a predetermined temperature (step S220).

Data on the multiple traveling candidate routes from the current position to the destination searched by the traveling candidate route searcher 120A may be outputted to the controller 160A via the bus line BL, and the controller 160A may cause the storage 210 to temporarily retain the data on the multiple traveling candidate routes.

The battery remaining capacity calculator 140A may calculate, based on the traveling condition, the battery remaining capacity that is upon the arrival of the own vehicle at the destination of corresponding one of the candidate routes searched by the traveling candidate route searcher 120A (step S230).

The data on the battery remaining capacity calculated by the battery remaining capacity calculator 140A may be outputted to the controller 160A via the bus line BL, and the controller 160A may cause the storage 210 to temporarily retain the data on the battery remaining capacity.

The traveling candidate route searcher 120A may search for traveling candidate routes in which the battery remaining capacity calculated by the battery remaining capacity calculator 140A in step S230 is equal to or more than a predetermined amount out of the searched multiple traveling candidate routes searched in step S220, may determine a recommended traveling route, and may present the determined recommended traveling route to the user to finish the processing (step S240).

### Workings and Example Effects

As described above, the vehicle navigation apparatus 1A according to the example embodiment may include the own vehicle position data acquirer 110, the traveling candidate route searcher 120A, the external data acquirer 130, and the battery remaining capacity calculator 140A. The own vehicle position data acquirer 110 may acquire the data on the position of the own vehicle. The traveling candidate route searcher 120A may search for one or more of the traveling candidate routes from the current position to the destination based on the data on the position of the own vehicle. The external data acquirer 130 may acquire the external data. The battery remaining capacity calculator 140A may calculate, for each of the searched multiple traveling candidate routes, the battery remaining capacity that is upon the arrival of the own vehicle at the destination of corresponding one of the searched traveling candidate routes based on the traveling condition. When there is a section where the temperature upon the passing of the own vehicle is equal to or lower than a predetermined temperature, based on the external data, the traveling candidate route searcher 120A may search for, out of the traveling candidate routes that include a route having the section where the own vehicle does not travel for predetermined time or more, the traveling candidate routes in which the battery remaining capacity is equal to or more than a predetermined amount.

For example, even when there is the section where the temperature upon the passing of the own vehicle is equal to or lower than a predetermined temperature, based on the external data, if the traveling time in this section is equal to or less than the predetermined time, it has been verified that no deterioration is seen even in the battery, mounted on the vehicle, of which the performance can possibly be deteriorated at a low temperature

Accordingly, when there is the section where the temperature upon the passing of the own vehicle is equal to or lower than a predetermined temperature, based on the external data, the traveling candidate route searcher 120A may search for traveling candidate routes in which the battery remaining capacity is equal to or more than a predetermined amount, out of the traveling candidate routes that include a route having the section where the own vehicle does not travel for predetermined time or more.

The use environment of the battery may be controlled even when the vehicle is mounted with the battery of which the performance can possibly be deteriorated due to the use environment. This accordingly helps to appropriately guide the vehicle to the destination and prevent deteriorated performance of the battery.

Based on those described above, the battery remaining capacity calculator 140A may calculate, based on the traveling condition, the battery remaining capacity that is upon the arrival of the own vehicle at the destination of corresponding one of the searched traveling candidate routes, for each of the searched multiple traveling candidate routes.

For example, instead of calculating the battery remaining capacity that is upon the arrival at the destination based on, in addition to the traveling condition, the temperature data as the external data upon passing through the searched multiple traveling candidate routes, the battery remaining capacity calculator 140A may calculate, based merely on the traveling condition, the battery remaining capacity that is upon the arrival of the own vehicle at the destination of corresponding one of the searched traveling candidate routes.

This helps to reduce processing load of the battery remaining capacity calculator 140A.

### Modification Example 2

In the example embodiment, the flow has been exemplified in which the series of processing are performed in the order of the processing of the external data acquisition (step S210), the processing of the traveling candidate route searching (step S220), and the processing of the battery remaining capacity calculation (step S230). However, the series of processing may be performed in the order of the processing of the traveling candidate route searching (step S220), the processing of the external data acquisition (step S210), the processing of the battery remaining capacity calculation (step S230), and processing of avoidance route searching.

### Third Example Embodiment

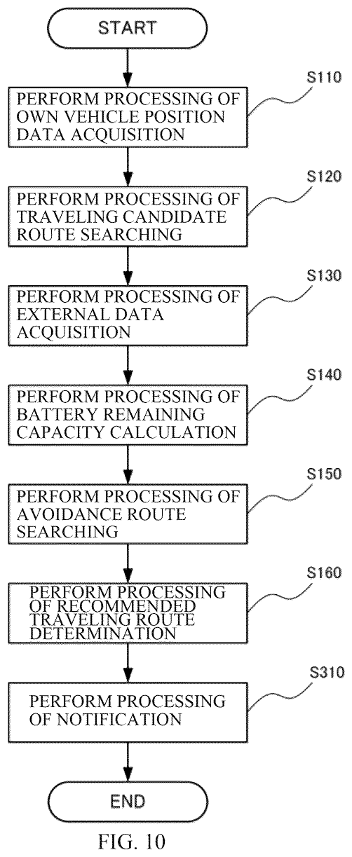

A description is given, with reference to FIGS. 9 and 10, of a vehicle navigation apparatus 1B according to the example embodiment.

### <Vehicle Navigation Apparatus 1B>

As illustrated in FIG. 9, the vehicle navigation apparatus 1B according to the example embodiment may include a processor 100B and a memory 200B.

The processor 100B may execute various pieces of processing in searching for traveling candidate routes.

In the example embodiment, for example, the processor 100B may acquire temperature data as the external data, may calculate a battery remaining capacity that is upon arrival at a destination based on the temperature data, and may search for traveling candidate routes in which the battery remaining capacity is equal to or more than a predetermined amount.

The processor 100B may transmit data on the searched traveling candidate routes and a reason for the searching to a user terminal.

Note that a detailed description is given later of the pieces of processing.

The memory 200B may include the read only memory (ROM) or the random access memory (RAM), for example, and may retain and store a program and various pieces of data.

In the example embodiment, the memory 200B may include the storage 210, and may retain and store, for example, a control program of the vehicle navigation apparatus 1, map data, or, for example, as acquired external data, data on temperatures in the traveling candidate routes, and text data related to the reason for the searching to be transmitted to the user terminal.

<Configuration of Processor 100n>

As illustrated in FIG. 9, the processor 100B of the vehicle navigation apparatus 1B according to the example embodiment may include the own vehicle position data acquirer 110, the traveling candidate route searcher 120, the external data acquirer 130, the battery remaining capacity calculator 140, the avoidance route searcher 150, a controller 160B, and a communicator 170.

As illustrated in FIG. 9, the above-described components may be coupled to one another via the bus line BL.

Note that components denoted by the same reference numerals as those in the first example embodiment and the second example embodiment have similar operations, and thus detailed descriptions thereof are omitted.

The controller 160B may execute processing of the entirety of the vehicle navigation apparatus 1B based on a control program stored, for example, in the read only memory (ROM) inside the storage 210.

In the example embodiment, the controller 160B may cause, for example, the communicator 170 to transmit, to the user terminal, the data on the traveling candidate routes searched by the traveling candidate route searcher 120 and the reason for the searching.

### <Processing of Vehicle Navigation Apparatus 1B>

A description is given, with reference to FIG. 10, of processing of the vehicle navigation apparatus 1B according to the example embodiment.

The own vehicle position data acquirer 110 may measure, for example, time in which radio waves constantly emitted from multiple satellites reach a receiver mounted on the own vehicle by utilizing the global navigation satellite system (GNSS) to acquire the data on the position of the own vehicle (step S110).

The data on the position of the own vehicle acquired by the own vehicle position data acquirer 110 may be outputted to the controller 160B described later via the bus line BL.

The traveling candidate route searcher 120 may search for the multiple traveling candidate routes from the current position to the destination based on the data on the position of the own vehicle, the destination data instructed by the user, and the map data stored in the storage 210 (step S120).

The data on the multiple traveling candidate routes from the current position to the destination searched by the traveling candidate route searcher 120 may be outputted to the controller 160B via the bus line BL, and the controller 160B may cause the storage 210 to temporarily retain the data on the multiple traveling candidate routes.

The external data acquirer 130 may acquire, as the external data, the data on temperatures that are upon traveling of the own vehicle in the traveling candidate routes searched by the traveling candidate route searcher 120, for example, from the user terminal to which an application program related to weather data is downloaded (step S130).

The data on temperatures that are upon traveling of the own vehicle in the traveling candidate routes acquired by the external data acquirer 130 may be outputted to the controller 160B via the bus line BL, and the controller 160B may cause the storage 210 to temporarily retain the data on the temperatures that are upon traveling of the own vehicle in the traveling candidate routes.

The battery remaining capacity calculator 140 may calculate, based on the traveling condition and the external data acquired by the external data acquirer 130, the battery remaining capacity that is upon the arrival of the own vehicle at the destination of corresponding one of the candidate routes searched by the traveling candidate route searcher 120 (step S140).

Data on the battery remaining capacity calculated by the battery remaining capacity calculator 140 may be outputted to the controller 160B via the bus line BL, and the controller 160B may cause the storage 210 to temporarily retain the data on the battery remaining capacity.

Based on the search result of the multiple traveling routes searched by the traveling candidate route searcher 120 in step S120 and the external data acquired by the external data acquirer 130 in step S130, for example, the avoidance route searcher 150 may search for an optimum avoidance route (step S150).

The traveling candidate route searcher 120 may search, with respect to the avoidance route searched by the avoidance route searcher 150, traveling candidate routes again in which the battery remaining capacity calculated by the battery remaining capacity calculator 140 in step S140 is equal to or more than a predetermined amount upon the arrival at the destination. The traveling candidate route searcher 120 may then determine a recommended traveling route, and may present the determined recommended traveling route to the user to finish the processing (step S160).

The controller 160B may then cause the communicator 170 to transmit, to the user terminal, the data on the traveling candidate routes searched again by the traveling candidate route searcher 120 and the reason for the searching to finish the processing (step S310).

### Workings and Example Effects

As described above, the vehicle navigation apparatus 1B according to the example embodiment may include the communicator 170 that transmits the data to the user terminal, and the communicator 170 may transmit, to the user terminal, the data on the traveling candidate routes searched by the traveling candidate route searcher 120 and the reason for the searching.

For example, in the vehicle navigation apparatus 1B according to the example embodiment, a traveling candidate route including a wide range of low-temperature areas in the traveling candidate route may be excluded, from the traveling candidate routes from the current position to the destination, even if the traveling candidate route has a short traveling distance.

Meanwhile, from the viewpoint of the user, when a traveling candidate route with an apparent short traveling distance is excluded, the user can possibly have suspicion about the search result unless no message is given.

Therefore, in the vehicle navigation apparatus 1B according to the example embodiment, the communicator 170 may transmit, to the user terminal, the data on the traveling candidate routes searched by the traveling candidate route searcher 120 and the reason for the searching.

The use environment of the battery may be controlled even when the vehicle is mounted with the battery of which the performance can possibly be deteriorated due to the use environment. This accordingly helps to appropriately guide the vehicle to the destination and prevent deteriorated performance of the battery.

In addition, it is possible to enhance reliance of the user on the search result.

### Modification Example 3

In the example embodiment, the flow has been exemplified in which the series of processing are performed in the order of the processing of the traveling candidate route searching (step S120), the processing of the external data acquisition (step S130), the processing of the battery remaining capacity calculation (step S140), and the processing of the avoidance route searching (step S150). However, the series of processing may be performed in the order of the processing of the external data acquisition (step S130), the processing of the traveling candidate route searching (step S120), and the processing of the battery remaining capacity calculation (step S140).

It is also possible to achieve at least the following example configurations (1) and (2) from the example embodiments and their modification examples described above.

(1)

A vehicle navigation apparatus to be applied to a vehicle, the vehicle navigation apparatus including:
one or more processors; and
one or more memories communicably coupled to the one or more processors,
the one or more processors each including
   a vehicle position data acquirer configured to acquire data on a position of the vehicle,
   a traveling candidate route searcher configured to search for traveling candidate routes from a current position of the vehicle to a destination of the vehicle based on the data on the position of the vehicle,
   an external data acquirer configured to acquire external data, and
   a battery remaining capacity calculator configured to calculate, for each of the searched traveling candidate routes, a remaining capacity of a battery that is upon arrival of the vehicle at the destination of corresponding one of the searched traveling candidate routes, based on a traveling condition and the acquired external data, in which
the external data acquirer is configured to acquire temperature data as the external data that is upon passing of the vehicle through corresponding one of the searched traveling candidate routes,
the battery remaining capacity calculator is configured to calculate the remaining capacity of the battery that is upon the arrival of the vehicle at the destination for each of the searched traveling candidate routes based on the temperature data, and
the traveling candidate route searcher is configured to search for one or more of the traveling candidate routes in which the remaining capacity of the battery is equal to or more than a predetermined amount.
   (2)

A vehicle navigation apparatus to be applied to a vehicle, the vehicle navigation apparatus including:
one or more processors; and
one or more memories communicably coupled to the one or more processors,
the one or more processors each including
   a vehicle position data acquirer configured to acquire data on a position of the vehicle,
   a traveling candidate route searcher configured to search for traveling candidate routes from a current position of the vehicle to a destination of the vehicle based on the data on the position of the vehicle,
   an external data acquirer configured to acquire external data, and
   a battery remaining capacity calculator configured to calculate, for each of the searched traveling candidate routes, a remaining capacity of a battery that is upon arrival of the vehicle at the destination of corresponding one of the searched traveling candidate routes based on a traveling condition, in which
the traveling candidate route searcher is configured, when there is a section where a temperature upon passing of the vehicle is equal to or lower than a predetermined temperature, to search for one or more of the traveling candidate routes in which the remaining capacity of the battery is equal to or more than a predetermined amount, based on the external data, out of the traveling candidate routes that include a traveling candidate route having the section where the vehicle does not travel for predetermined time or more.

In some embodiments, it is possible to implement the vehicle navigation apparatus 1, 1A, or 1B of the example embodiment of the disclosure by recording the process to be executed by the processor 100, 100A, or 100B on a non-transitory recording medium readable by a computer system, and causing the computer system to load the program recorded on the non-transitory recording medium onto the processor 100, 100A, or 100B to execute the program. The computer system as used herein may encompass an operating system (OS) and a hardware such as a peripheral device.

In addition, when the computer system utilizes a World Wide Web (WWW) system, the “computer system” may encompass a website providing environment (or a website displaying environment). The program may be transmitted from a computer system that contains the program in a storage device or the like to another computer system via a transmission medium or by a carrier wave in a transmission medium. The “transmission medium” that transmits the program may refer to a medium having a capability to transmit data, including a network (e.g., a communication network) such as the Internet and a communication link (e.g., a communication line) such as a telephone line.

Further, the program may be directed to implement a part of the operation described above. The program may be a so-called differential file (differential program) configured to implement the operation by a combination of a program already recorded on the computer system.

Although some example embodiments of the disclosure have been described in the foregoing by way of example with reference to the accompanying drawings, the disclosure is by no means limited to the embodiments described above. It should be appreciated that modifications and alterations may be made by persons skilled in the art without departing from the scope as defined by the appended claims. The disclosure is intended to include such modifications and alterations in so far as they fall within the scope of the appended claims or the equivalents thereof.

The limitations in the claims are to be interpreted broadly based on the language employed in the claims and not limited to examples described in this specification or during the prosecution of the application, and the examples are to be construed as non-exclusive.

As used in this specification and the appended claims, the singular forms “a,” “an,” and “the” include, especially in the context of the claims, are to be construed to cover both the singular and the plural, unless otherwise indicated herein or clearly contradicted by context.

Throughout this specification and the appended claims, unless the context requires otherwise, the terms “comprise”, “include”, “have”, and their variations are to be construed to cover the inclusion of a stated element, integer, or step but not the exclusion of any other non-stated element, integer, or step.

The use of the terms first, second, etc. do not denote any order or importance, but rather the terms first, second, etc. are used to distinguish one element from another.

The term “substantially”, “approximately”, “about”, and its variants having the similar meaning thereto are defined as being largely but not necessarily wholly what is specified as understood by one of ordinary skill in the art.

The term “disposed on/provided on/formed on” and its variants having the similar meaning thereto as used herein refer to elements disposed directly in contact with each other or indirectly by having intervening structures therebetween.

The processor 100, 100A, or 100B illustrated in FIG. 1, 5, or 9 is implementable by circuitry including at least one semiconductor integrated circuit such as at least one processor (e.g., a central processing unit (CPU)), at least one application specific integrated circuit (ASIC), and/or at least one field programmable gate array (FPGA). At least one processor is configurable, by reading instructions from at least one machine readable non-transitory tangible medium, to perform all or a part of functions of the processor 100, 100A, or 100B. Such a medium may take many forms, including, but not limited to, any type of magnetic medium such as a hard disk, any type of optical medium such as a CD and a DVD, any type of semiconductor memory (i.e., semiconductor circuit) such as a volatile memory and a non-volatile memory. The volatile memory may include a DRAM and a SRAM, and the nonvolatile memory may include a ROM and a NVRAM. The ASIC is an integrated circuit (IC) customized to perform, and the FPGA is an integrated circuit designed to be configured after manufacturing in order to perform, all or a part of the functions of the processor 100, 100A, or 100B illustrated in FIG. 1, 5, or 9.

1. A vehicle navigation apparatus to be applied to a vehicle, the vehicle navigation apparatus comprising:
a vehicle position data acquirer configured to acquire data on a position of the vehicle;
a traveling candidate route searcher configured to search for traveling candidate routes from a current position of the vehicle to a destination of the vehicle based on the data on the position of the vehicle;
an external data acquirer configured to acquire external data; and
a battery remaining capacity calculator configured to calculate, for each of the searched traveling candidate routes, a remaining capacity of a battery that is upon arrival of the vehicle at the destination of corresponding one of the searched traveling candidate routes, based on a traveling condition and the acquired external data, wherein
the external data acquirer is configured to acquire temperature data as the external data that is upon passing of the vehicle through corresponding one of the searched traveling candidate routes,
the battery remaining capacity calculator is configured to calculate the remaining capacity of the battery that is upon the arrival of the vehicle at the destination for each of the searched traveling candidate routes based on the temperature data, and
the traveling candidate route searcher is configured to search for one or more of the traveling candidate routes in which the remaining capacity of the battery is equal to or more than a predetermined amount.

2. A vehicle navigation apparatus to be applied to a vehicle, the vehicle navigation apparatus comprising:
a vehicle position data acquirer configured to acquire data on a position of the vehicle;
a traveling candidate route searcher configured to search for traveling candidate routes from a current position of the vehicle to a destination of the vehicle, based on the data on the position of the vehicle;
an external data acquirer configured to acquire external data; and
a battery remaining capacity calculator configured to calculate, for each of the searched traveling candidate routes, a remaining capacity of a battery that is upon arrival of the vehicle at the destination of corresponding one of the searched traveling candidate routes based on a traveling condition, wherein
the traveling candidate route searcher is configured, when there is a section where a temperature upon passing of the vehicle is equal to or lower than a predetermined temperature, to search for one or more of the traveling candidate routes in which the remaining capacity of the battery is equal to or more than a predetermined amount, based on the external data, out of the traveling candidate routes that comprise a traveling candidate route comprising the section where the vehicle does not travel for predetermined time or more.

3. The vehicle navigation apparatus according to claim 1, wherein the external data acquirer is configured to acquire, based on a user terminal, the temperature data as the external data that is upon passing of the vehicle through corresponding one of the searched traveling candidate routes.

4. The vehicle navigation apparatus according to claim 1, wherein the external data acquirer is configured to acquire, based on a user terminal, the temperature data as the external data that is upon passing of the vehicle through corresponding one of the searched traveling candidate routes.

5. The vehicle navigation apparatus according to claim 3, wherein the battery comprises an iron phosphate-based lithium-ion battery.

6. The vehicle navigation apparatus according to claim 1, further comprising a communicator configured to transmit data to a user terminal, wherein
the communicator is configured to transmit, to the user terminal, data on the traveling candidate routes searched by the traveling candidate route searcher and a reason for the searching.

7. The vehicle navigation apparatus according to claim 2, further comprising a communicator configured to transmit data to a user terminal, wherein
the communicator is configured to transmit, to the user terminal, data on the traveling candidate routes searched by the traveling candidate route searcher and a reason for the searching.

8. A vehicle navigation apparatus to be applied to a vehicle, the vehicle navigation apparatus comprising
circuitry configured to
acquire data on a position of the vehicle,
search for traveling candidate routes from a current position of the vehicle to a destination of the vehicle based on the data on the position of the vehicle,
acquire external data, and
calculate, for each of the searched traveling candidate routes, a remaining capacity of a battery that is upon arrival of the vehicle at the destination of corresponding one of the searched traveling candidate routes, based on a traveling condition and the acquired external data, wherein
the circuitry is configured to
acquire temperature data as the external data that is upon passing of the vehicle through corresponding one of the searched traveling candidate routes,
calculate the remaining capacity of the battery that is upon the arrival of the vehicle at the destination for each of the searched traveling candidate routes based on the temperature data, and
search for one or more of the traveling candidate routes in which the remaining capacity of the battery is equal to or more than a predetermined amount.

9. A vehicle navigation apparatus to be applied to a vehicle, the vehicle navigation apparatus comprising
circuitry configured to
acquire data on a position of the vehicle,
search for traveling candidate routes from a current position of the vehicle to a destination of the vehicle based on the data on the position of the vehicle,
acquire external data, and
calculate, for each of the searched traveling candidate routes, a remaining capacity of a battery that is upon arrival of the vehicle at the destination of corresponding one of the searched traveling candidate routes based on a traveling condition, wherein
the circuitry is configured to
search, when there is a section where a temperature upon passing of the vehicle is equal to or lower than a predetermined temperature, for one or more of the traveling candidate routes in which the remaining capacity of the battery is equal to or more than a predetermined amount, based on the external data, out of the traveling candidate routes that comprise a route comprising the section where the vehicle does not travel for predetermined time or more.
